(19) United States
(12) Patent Application Publication
(10) Pub. No.: US 2022/0158418 A1
(43) Pub. Date: May 19, 2022

(54) LIGHT SOURCE DEVICE, DETECTION DEVICE, AND ELECTRONIC APPARATUS

(71) Applicants: Takumi SATOH, Miyagi (JP); Toshiyuki IKEOH, Düsseldorf (DE); Kazuma IZUMIYA, Miyagi (JP); Tsuyoshi UENO, Kanagawa (JP)

(72) Inventors: Takumi SATOH, Miyagi (JP); Toshiyuki IKEOH, Düsseldorf (DE); Kazuma IZUMIYA, Miyagi (JP); Tsuyoshi UENO, Kanagawa (JP)

(21) Appl. No.: 17/431,184

(22) PCT Filed: Mar. 11, 2020
(86) PCT No.: PCT/JP2020/010664

§ 371 Date: Aug. 16, 2021

(30) Foreign Application Priority Data
Mar. 14, 2019 (JP) 2019-046772
Dec. 13, 2019 (JP) 2019-225299

(51) Int. Cl. H01S 5/42; H01S 5/183; G01S 17/894; G01S 17/931

(52) U.S. Cl. CPC H01S 5/423; G01S 17/931; G01S 17/894; H01S 5/18388

(57) ABSTRACT

A light source device includes a light source and a projection optical system. The light source includes a plurality of light emitters. The projection optical system is configured to emit light emitted from the light source. A light emission amount per unit area in a light emission region of the light source corresponding to an irradiated region where a magnification of the projection optical system is relatively large, is larger than a light emission amount per unit area in a light emission region corresponding to an irradiated region where a magnification of the projection optical system is relatively small.

### TECHNICAL FIELD

The present invention relates to a light source device, a detection device, and an electronic apparatus.

### BACKGROUND ART

In recent years, light detection devices that irradiate an object with light, receive the light returning from the object, and detect the state of the object are being utilized in diverse fields. A rider system is for example disclosed in patent literature 1 that detects the presence of an object and measures the distance to the target object by the laser beam. The rider system includes a light source device that utilizes a vertical cavity surface emitting laser (VCSEL) as a light source and emits light emitted from the VCSEL through the lens.

### CITATION LIST

### Patent Literature

PTL 1: Japanese Laid-open Patent Publication No. 2007-214564

### SUMMARY OF INVENTION

### Technical Problem

When light from a light source widened by a projection optical system is emitted in a wide range, the light illuminance on the irradiated surface may be non-uniform due to an aberration in the projection optical system. In light source devices of the known art, no study focused on this type of problem of achieving uniform illuminance on the irradiated surface. However, in detection devices that receive and detect reflected light, improving the detection accuracy is extremely important when projecting light from a light source device uniformly onto an irradiated surface.

The present invention is rendered based on an awareness of the above described problem, and has the object of providing a light source device with superior illuminance uniformity of the irradiated light.

### Solution to Problem

According to an aspect of the present invention, a light source device includes a light source and a projection optical system. The light source includes a plurality of light emitters. The projection optical system is configured to emit light emitted from the light source. A light emission amount per unit area in a light emission region of the light source corresponding to an irradiated region where a magnification of the projection optical system is relatively large, is larger than a light emission amount per unit area in a light emission region corresponding to an irradiated region where a magnification of the projection optical system is relatively small.

### Advantageous Effects of Invention

An aspect of the present invention can therefore achieve a light source device with superior uniformity of illuminance of irradiated light, by setting the light emitting amount of the light source so as to cancel out irregularities in the illuminance caused by the projection optical system.

### BRIEF DESCRIPTION OF DRAWINGS

FIG. 1 is a drawing illustrating a concept view of a distance measurement device as an embodiment of the detection device applying a light source device of the present invention.

FIG. 2A is a drawing illustrating the standard state of the projection optical system in the light source device, and illustrates the structure of the light source device.

FIG. 2B is a drawing illustrating the standard state of the projection optical system in the light source device, and illustrates the illuminance state of the light on the irradiated surface by the light source device.

FIG. 3A is a drawing illustrating the irradiated region adjustment state of the projection optical system in the light source device, and illustrates the structure of the light source device.

FIG. 3B is a drawing illustrating the irradiated region adjustment state of the projection optical system in the light source device, and illustrates the illuminance state of the light on the irradiated surface by the light source device.

FIG. 4 is cross-sectional view illustrating the light source device in a state including an adjustment mechanism.

FIG. 5 is a cross-sectional view illustrating a portion of the light source of the light source device.

FIG. 6 is a graph illustrating the illuminance distribution on the irradiated surface when a plurality of light emitters in the light source is arranged at regular intervals, and when the light emitters are installed in a coarse and dense placement.

FIG. 7 is a drawing illustrating a state of the light emitters installed in a coarse and dense placement in the light source of the light source device.

FIG. 8 is a graph illustrating the illuminance distribution on the irradiated surface when the light emitters of the light source emit light at uniform light amounts, and when the light emitters emit light at different light amounts.

FIG. 9 is a drawing illustrating a state when the light emitters in the light source of the light source device emit light at different light amounts.

FIG. 10 is a drawing illustrating an example of the setting range of the light emitters in the light source of the light source device.

FIG. 11A is a drawing illustrating the irradiated region of the light on the irradiated surface, and illustrating when the light emitters are placed on the entire rectangular light emitting surface.

FIG. 11B is a drawing illustrating the irradiated region of the light on the irradiated surface, and illustrating when the light emitters are placed in an oval shape.

FIG. 12 is a drawing illustrating an example of applying the light source device to a detection device for article inspections.

FIG. 13 is a drawing illustrating an example of applying the detection device including the light source device to a movable device.

FIG. 14 is a drawing illustrating an example of applying the detection device including the light source device in a portable information terminal.

FIG. 15 is a drawing illustrating an example of applying the detection device including the light source device to a driver support system for a moving unit.

FIG. 16 is a drawing showing an example of applying the detection device including the light source device to an autonomous movement system for the moving unit.

### DESCRIPTION OF EMBODIMENTS

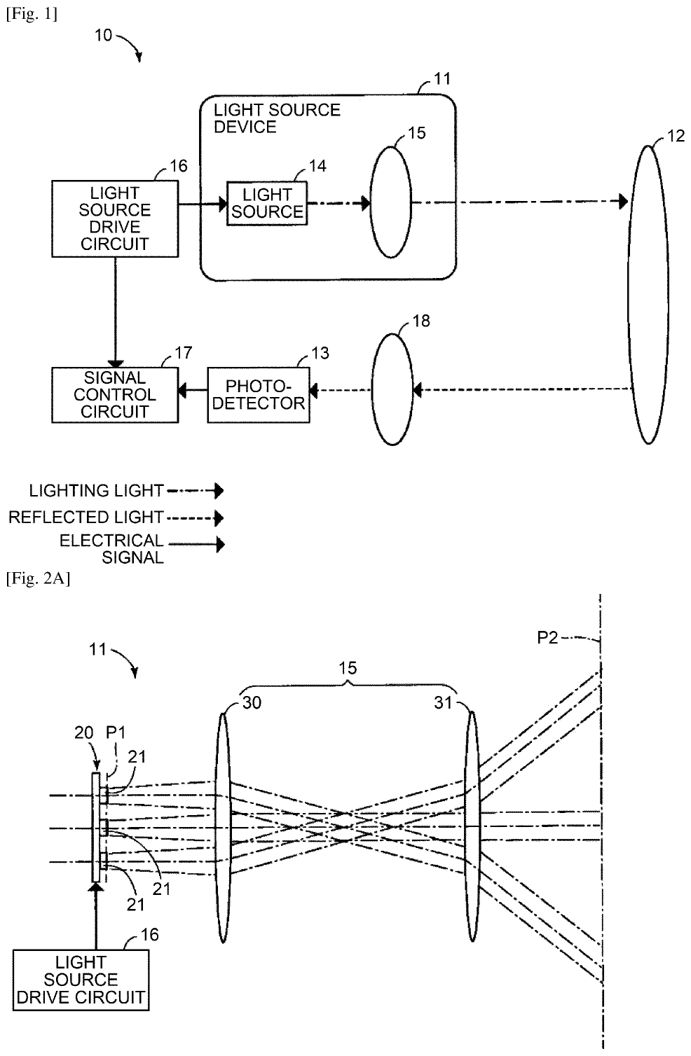

The embodiments of the present invention are described next while referring to the accompanying drawings. FIG. 1 illustrates a concept view of a distance measurement device 10. The distance measurement device 10 is a distance detection device utilizing the time of flight (TOF) technique that projects (emits) pulsed light from a light source device 11 onto a detection target object 12, receives the reflected light from the detection target object 12 by a photodetector 13, and measures the distance to the detection target object 12 based on the time required to receive the reflected light.

As illustrated in FIG. 1, the light source device 11 includes a light source 14 and a projection optical system 15. Light emission of the light source 14 is controlled by way of the electrical current from a light source drive circuit 16. The light source drive circuit 16 sends a signal to a signal control circuit 17 when the light source 14 emits light. The projection optical system 15 is an optical system that widens (diffuses) the light emitted from the light source 14 and projects it onto the detection target object 12.

The reflected light that is reflected by the detection target object 12 after being projected onto it from the light source device 11 is optically guided to the photodetector 13 by way of a light-receiving optical system 18 having a light collecting (focusing) function. The photodetector 13 includes a photoelectric conversion element, the light that the photodetector 13 receives is photo-electrically converted and sent as an electrical signal to the signal control circuit 17. The signal control circuit 17 calculates the distance to the detection target object 12 based on the time difference between the projected light (light emission signal input from the light source drive circuit 16) and the received light (received light signal input from the photodetector 13). Therefore, in the distance measurement device 10, the photodetector 13 functions as a detector that detects light emitted from the light source device 11 that is reflected by the detection target object 12. The signal control circuit 17 functions as a calculator that obtains information relating to the distance to the detection target object 12 based on a signal from the photodetector 13 (detector part).

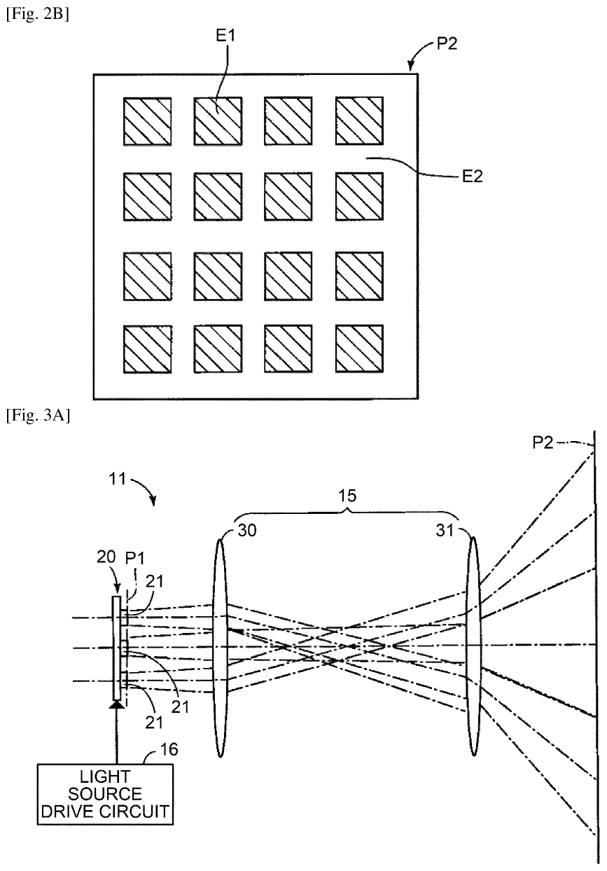

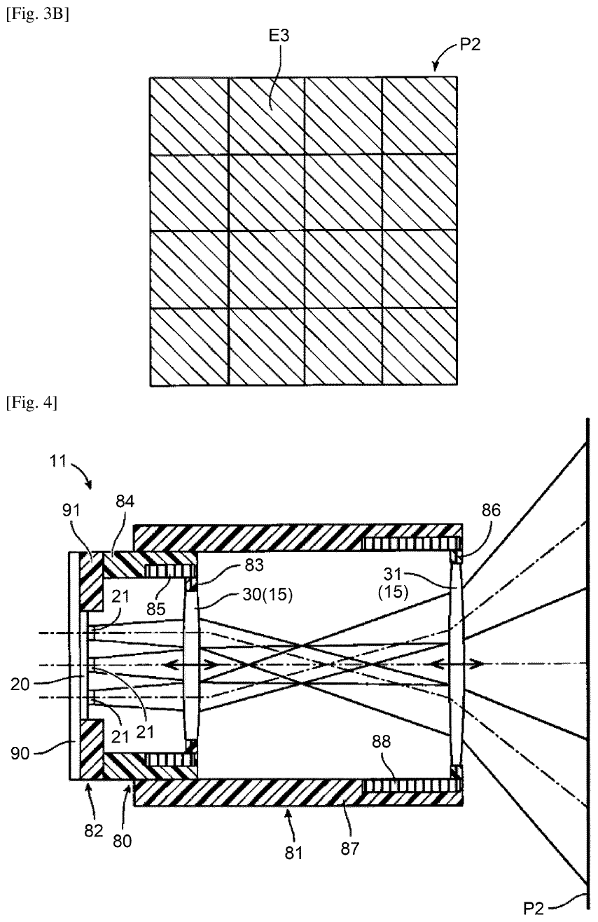

FIG. 2A and FIG. 3B illustrate the structure of the light source device 11. The light source device 11 includes a surface emitting laser 20 as the above described light source 14 (FIG. 1). The surface emitting laser 20 includes a plurality of surface emitting laser elements 21 installed at predetermined relative positions on a light emitting surface P1. In the present invention, the surface emitting laser 20 is one example of the light source, and the surface emitting laser elements 21 are one example of the light emitters in the present invention. A surface emitting laser element 21 of the present embodiment is a vertical cavity surface emitting laser (hereafter, referred to VCSEL) that emits light in the perpendicular direction to the substrate.

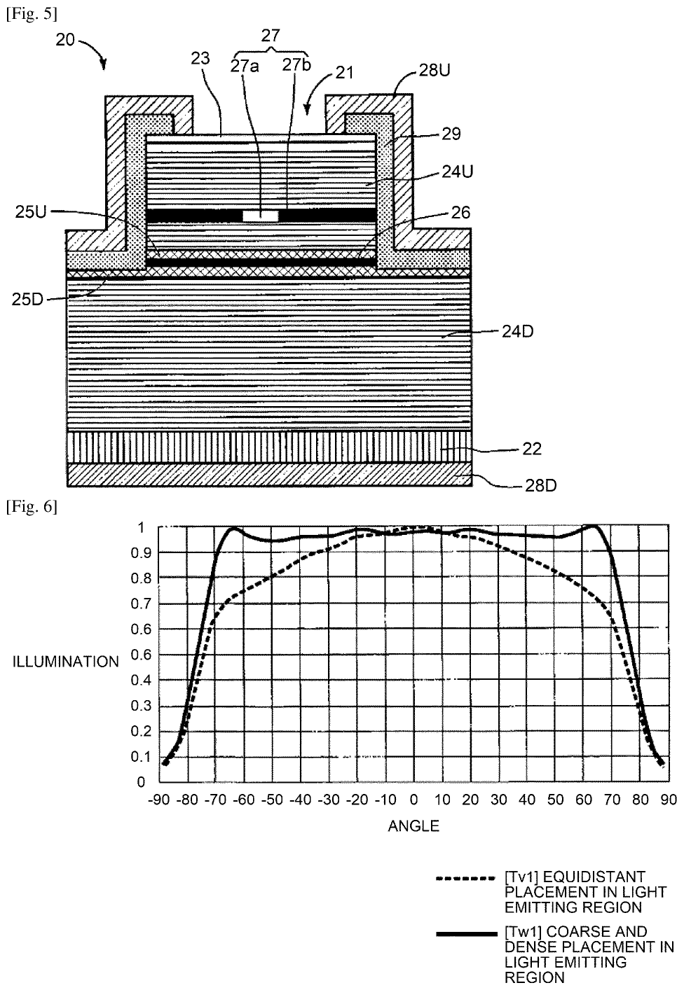

A partial cross-sectional structure of the surface emitting laser 20 corresponding to each of the surface emitting laser elements 21 is illustrated in FIG. 5. A lower multilayer film reflecting mirror 24D, a lower spacer layer 25D, an active layer 26, an upper spacer layer 25U, an upper multilayer film reflecting mirror 24U, and a contact layer 23 are formed in laminated layers on a substrate 22. A current constriction layer 27 is formed within the upper multilayer film reflecting mirror 24U. The current constriction layer 27 includes a current pass-through region 27a, and a current passage suppression region 27b enclosing the current pass-through region 27a. A lower electrode 28D is formed below the substrate 22 and an upper electrode 28U is formed at the uppermost area. The inner part of the upper electrode 28U is insulated by an insulating piece 29. The upper electrode 28U contacts the periphery (edge) of the contact layer 23, and there is an opening at the center area of the contact layer 23.

When each of the electrodes 28U and 28D apply electrical current to the active layer 26, amplification occurs in the upper multilayer film reflecting mirror 24U and the lower multilayer film reflecting mirror 24D on the laminated structure and a laser beam is oscillated. The emission intensity of the laser beam is changed according to the applied current amount. The current constriction layer 27 boosts the efficiency of the electric current applied to the active layer 26 and lowers an oscillation threshold value. The maximum current amount that can be applied increases as the current pass-through region 27a of the current constriction layer 27 becomes larger (widens), and the maximum output of the laser beam that can be oscillated increases, but on the other hand has the characteristic of raising the oscillation threshold.

Compared to edge emitting lasers, characteristics of VCSEL include easily forming light emitting elements into two-dimensional arrays, allowing multi-point beams by dense placement of light emitting elements. The VCSEL also allows a high degree of freedom in placement of light emitting elements and except for structural restrictions such as on the placement of electrodes, can be installed at any optional position on the substrate.

As illustrated in FIG. 2A and FIG. 3A, the projection optical system 15 includes a condenser lens 30 that is a condensing optical element, and a projection lens 31 that is a magnifying optical element. The condenser lens 30 is a lens having positive power, and suppresses the divergence angle of the light emitted from each of the surface emitting laser elements 21 of the surface emitting laser 20 and is capable of forming a conjugate image from each of the surface emitting laser elements 21. The projection lens 31 is a lens having negative power, and magnifies the irradiation angle of the light transmitted through the condenser lens 30 and emits light, and projects the light onto an irradiated region of a wider range than the light emitting surface P1 of the surface emitting laser 20. The curvature of the lens surface of the projection lens 31 determines the range of the irradiated region and the extent of magnification of the conjugate image.

The structure of the projection optical system of the present invention is not limited to the example illustrated in FIG. 2A and FIG. 3A. The condensing optical element that configures the projection optical system 15 needs only to suppress the divergence angle of the light from the light source (the surface emitting laser 20), and aside from the lens may utilize diffraction gratings, etc. When utilizing a lens in the condensing optical element, a common lens capable of passing light from a plurality of the surface emitting laser elements 21 may be utilized, or a microlens array including a plurality of lenses corresponding to each of the surface emitting laser elements 21 may be utilized. The projection optical element in the projection optical system 15 need only widen the light, and an optional item such as a biconcave lens, a negative meniscus lens, or a diffuser panel may be utilized. When using a lens with either of the condensing optical element or the projection optical element, the number of lenses arrayed along the optical axial direction may be a single (single lens) or may be a lens group of a plurality of lenses.

FIG. 2A illustrates a state of the light source device 11 having a focal length for the condenser lens 30 equivalent to the distance from light emitting surface P1 of the surface emitting laser 20 to the condenser lens 30. This state is the standard state of the projection optical system 15 in the light source device 11. In the standard state of the projection optical system 15, the light from each of the surface emitting laser elements 21 of the surface emitting laser 20 is collimated by the condenser lens 30 and after being transmitted through the condenser lens 30, a conjugate image from each surface emitting laser element 21 is formed regardless of the position along the light path. In other words, the light emitting surface P1 and an irradiated surface P2 are an approximately conjugate relation. The irradiated surface P2 is a theoretical plane that is set to simplify the understanding of the optical state, and the actual detection target object 12 may be any of various shapes and is not limited to a flat surface.

The irradiated region on the irradiated surface P2 in the standard state of the projection optical system 15 is illustrated in FIG. 2B. In the surface emitting laser 20, there are respective gaps between the surface emitting laser elements 21 so that discrete (between the mutual gaps) irradiated regions E1 appear on the irradiated surface P2 in the standard state forming a conjugate image from each of the surface emitting laser elements 21. More specifically, the irradiated region E1 is a region that the light is emitted onto the irradiated surface P2, and a plurality of irradiated regions E1 are present in a positional relationship corresponding to the surface emitting laser elements 21 of the surface emitting laser 20. There are also non-irradiated regions E2 (regions not irradiated with light) that have low illuminance compared to the irradiated regions E1 between the individual irradiated regions E1. The non-irradiated regions E2 are regions corresponding to the gap portions between the surface emitting laser elements 21 of the surface emitting laser 20. In other words, in the standard state of the projection optical system 15, the distributed (discrete) illuminance on the irradiated surface P2 becomes stronger and uniform illuminance cannot be obtained.

FIG. 3A illustrates a state that the condenser lens 30 is slightly shifted from the standard state of the projection optical system 15 (FIG. 2A) to the object side (the side approaching the light emitting surface P1) in the optical axial direction. This state is the irradiated region adjustment state of the projection optical system 15 of the light source device 11. In the irradiated region adjustment state, by shifting the condenser lens 30, the light from each of the surface emitting laser elements 21 diverges without being completely collimated, and compared to the standard state, the image from each of the surface emitting laser elements 21 widens. As a result, as illustrated in FIG. 3B, on the irradiated surface P2, a fully irradiated region E3 irradiated with the light so as to fill the region corresponding to the gaps between the surface emitting laser elements 21 is obtained.

How far to shift the condenser lens 30 from the standard state to the irradiated region adjustment state will differ depending on the projection optical system 15, the specifications for the surface emitting laser 20, and each type of condition. In the structure of the present embodiment, the fully irradiated region E3 with a wide angle and moreover uniform luminance is obtained by shifting the condenser lens 30 to the object side (the side approaching the light emitting surface P1) in a range from 15% to 24%, relative to the distance from the light emitting surface P1 of the surface emitting laser 20 to the condenser lens 30 (equivalent to focal length of the condenser lens 30) in the standard state. When the amount that the condenser lens 30 is shifted falls below the lower limit (15%) of the above described range, the irradiated region on the irradiated surface P2 corresponding to each of the surface emitting laser elements 21 contracts and the non-irradiated regions E2 appear as illustrated in FIG. 2B. When the amount that the condenser lens 30 is shifted exceeds the upper limit (24%) of the above described range, the incident angle of the light onto the projection lens 31 becomes too large, the effect from aberrations on the irradiated region at the irradiated surface P2 may become large, and the luminance uniformity may become worse.

On the projection optical system 15, besides the above described method for shifting the position of the condenser lens 30 in the optical axial direction, a method for changing the lens surface curvature of the projection lens 31 can also achieve the projection that does not emit light onto the non-irradiated region E2. More specifically, a conjugate image from each of the surface emitting laser elements 21 is input (incident) to the projection lens 31 and set to widen the image from each of the surface emitting laser elements 21 by setting the curvature of the lens surface of the projection lens 31. Moreover, the projection lens 31 is in this way selected to obtain an appropriate irradiated range (fully irradiated region E3) not including the non-irradiated region E2. This method can be applied just by exchanging the projection lens 31 according to the target irradiation range, without changing the combination and the layout of the condenser lens 30 and the surface emitting laser 20, and also reduces the worker's burden of having to perform settings and adjustments.

For the method that adjusts the irradiated area on the projection optical system 15, the method that shifts the position of the condenser lens 30 in the optical axial direction can be concomitantly used with the method that changes the curvature of the lens surface of the projection lens 31 (exchanges the projection lens 31).

In the distance measurement device 10 in FIG. 1, the contour and the placement of the photodetector 13 (FIG. 1) relate correspondingly to the irradiated region of the light projected from the light source device 11. The correlation between the light emitted from the surface emitting laser elements 21 of the surface emitting laser 20 and the light reflected from the detection target object 12 and received by the photodetector 13 is in this way maintained, and accurate detection (distance) can be performed for each irradiated region corresponding to each of the surface emitting laser elements 21.

To obtain the fully irradiated region E3 as illustrated in FIG. 3B, the position of the projection optical system 15 configuring the light source device 11 must be appropriately placed just as in the design value calculated for the position of the surface emitting laser 20. For example, when the position of the condenser lens 30 configuring the projection optical system 15 shifts to the optical axial direction relative to the design value, the conjugate image of each surface emitting laser element 21 is formed on the irradiated surface P2 as shown in FIG. 2B causing concern that the non-irradiated region E2 on the irradiated surface P2 will increase. The projection lens 31 configuring the projection optical system 15 must also be installed just as specified by the design value.

When there is a shift in the position in the perpendicular direction on the optical axis, between the projection optical system 15 and the surface emitting laser 20, the light emission angle of the light emitted from the light source device 11 will shift (deviate). When the light emission angle of the light emitted from the light source device 11 shifts (deviates) greatly from the field angle of the light-receiving optical system 18 (FIG. 1), the non-irradiated region that does not receive the reflected light through the light-receiving optical system 18 increases so that the range capable of being detected by the distance measurement device 10 consequently contracts.

The light source device 11 in the state including an adjuster mechanism for adjusting the position of the optical element in order to prevent the above circumstances and obtain the performance just as designed is illustrated in FIG. 4. The light source device 11 illustrated in FIG. 4 includes a first position adjuster 80 that supports the condenser lens 30 such that the position thereof is adjustable, a second position adjuster 81 that supports the projection lens 31 such that the position thereof is adjustable, and a third position adjuster 82 that supports the surface emitting laser 20 such that the position thereof is adjustable relative to the projection optical system 15.

The first position adjuster 80 is hereafter described. The condenser lens 30 is supported on the inner side of a lens holder 83, and the lens holder 83 is installed on the inner side of a condenser lens barrel 84. The lens holder 83 is supported by way of a moving part 85 to allow movement along the optical axial direction relative to the condenser lens barrel 84. The moving part 85 includes a female screw (helicoid) formed on the inner circumferential surface of the condenser lens barrel 84, and a male screw on the outer circumferential portion of the lens holder 83 is threadably mounted on the female screw. The lens holder 83 moves in the optical axial direction for allowing position adjustment while rotating around the optical axis of the condenser lens 30 as the center along the female screw in the moving part 85. The forming range (range that the female screw is formed in the condenser lens barrel 84) in the optical axial direction of the moving part 85 as illustrated in FIG. 4 is the movable range of the condenser lens 30.

The second position adjuster 81 is hereafter described. The projection lens 31 is supported on the inner side of a lens holder 86, and the lens holder 86 is installed on the inner side of a projection lens barrel 87. The projection lens barrel 87 is installed on the outer side of the condenser lens barrel 84, and the center axis of the condenser lens barrel 84 and the center axis of the projection lens barrel 87 are positioned concentrically. The lens holder 86 is supported via a moving part 88 to allow movement in the optical axial direction relative to the projection lens barrel 87. The moving part 88 includes a female screw (helicoid) formed on the inner circumferential surface of the projection lens barrel 87, and in this structure, a male screw on the outer circumferential portion of the lens holder 86 threadably engages with the female screw. The lens holder 86 moves in the optical axial direction for allowing position adjustment while rotating around the optical axis of the projection lens 31 as the center along the female screw of the moving part 88. The forming range (range that the female screw is formed in the projection lens barrel 87) in the optical axial direction of the moving part 88 as illustrated in FIG. 4 is the movable range of the projection lens 31.

The first position adjuster 80 and the second position adjuster 81 will prove sufficient if capable of accurately controlling the position of the lens holder 83, and are not limited to a screw mechanism such as the moving part 85 and the moving part 85 as described above. As a modification, a structure may be employed that a cam (cam groove) rather than the female screw may be formed on the circumferential surface of the condenser lens barrel 84 and the circumferential surface of the projection lens barrel 87, and a cam follower is installed on the lens holder 83 and the lens holder 86 that moves the lens holder 83 and the lens holder 86 in the optical path direction by guiding the cam follower by way of the cam. Alternatively, a structure may be employed so that the lens holder 83 and the lens holder 86 are supported to allow movement relative to the guide part (guide shaft, guide groove, etc.) extending in the optical path direction, the lens holder 83 and the lens holder 86 are threadably engaged by way of a feed screw extending in the optical path direction, so that the lens holder 83 and the lens holder 86 are guided by the guide part to allow movement in the optical path direction by the rotation of the feed screw. The drive power for the moving the lens holder 83 and the lens holder 86 in the optical path direction may be applied manually or may be applied by a drive device such as a motor.

When the position of the condenser lens 30 or the projection lens 31 has deviated from the design value, lighting onto the irradiated surface P2 by the fully irradiated region E3 (FIG. 3B) having no non-irradiated region may easily be achieved by adjusting the position by utilizing the first position adjuster 80 and the second position adjuster 81.

The third position adjuster 82 is hereafter described. The surface emitting laser 20 is supported on an electronic circuit board 90. Components necessary for driving the surface emitting laser 20 such as the light source drive circuit 16 (FIG. 1) are mounted on the electronic circuit board 90. The electronic circuit board 90 is supported relative to the condenser lens barrel 84 by way of an adjuster mechanism 91 to allow movement in at least two different directions perpendicular to the light axis. By moving the electronic circuit board 90 relative to the condenser lens barrel 84, the position of the surface emitting laser 20 can be changed (namely, along the light emitting surface P1 illustrated in FIG. 2A or FIG. 3A) on the plane perpendicular to the light axis. The adjuster mechanism 91 is open in the center area at the surface emitting laser 20 position, and so does not block the light emitted from each of the surface emitting laser elements 21.

The structure of the adjuster mechanism 91 for the third position adjuster 82 can be appropriately selected. One example is a structure employing a dual-step movement stage in the adjuster mechanism 91. The first step of the movement stage and the second step of the movement stage in the adjuster mechanism 91 are combined so as to allow relative movement along the first guide part (guide axis and guide groove, etc.) extending in a first direction perpendicular to the light axis. The first step of the movement stage is fixed to the electronic circuit board 90. The second step of the movement stage is supported to allow movement along the second guide part (guide axis and guide groove, etc.) extending in a second direction (direction different from the first direction) perpendicular to the light axis, relative to the condenser lens barrel 84. This type of structure allows changing the positional relationship between the electronic circuit board 90 and the condenser lens barrel 84 (and the projection lens barrel 87) in an optional direction perpendicular to the light axis. The drive power for moving each movement stage of the adjuster mechanism 91 in a direction perpendicular to the light axis may be applied manually or may be applied by a drive device such as a motor.

As a different example of the third position adjuster 82, an insertion part fixed to the electronic circuit board 90 is inserted into the interior of the condenser lens barrel 84. Three or more support parts capable of changing the amount of protrusion in the inward radial direction are installed on the condenser lens barrel 84 at different positions in the circumferential direction. The position of the electronic circuit board 90 is set by supporting the insertion part by way of these support parts. Changing the relative amount of protrusion of each support part in the inward radial direction of the condenser lens barrel 84 allows adjusting the position of the electronic circuit board 90 relative to the condenser lens barrel 84 in a direction perpendicular to the light axis.

The condenser lens barrel 84 and the projection lens barrel 87 are configured to match the light axis of the respectively supported condenser lens 30 and the light axis of the projection lens 31. Then, by utilizing the third position adjuster 82, the centers of the surface emitting laser 20 relative to the optical axis of the condenser lens 30 and the projection lens 31 can be aligned by adjusting the position of the surface emitting laser 20 and the electronic circuit board 90 relative to the condenser lens barrel 84 and the projection lens barrel 87. Deviations in the emission angle of light emitted from the light source device 11 can in this way be prevented, and the non-irradiated region from the light source device 11 relative to the light-receiving field angle in the light-receiving optical system 18 can be reduced, so that the distance measuring accuracy in the distance measurement device 10 can be improved.

As described above, by utilizing the first position adjuster 80, the second position adjuster 81, and the third position adjuster 82, to adjust the respective positional relationships of the surface emitting laser 20, the condenser lens 30, and the projection lens 31, the mounting deviations of each portion of the light source device 11 relative to the design values and the positional deviations of each portion of the light source device 11 that occur over time along with usage by the user can be easily corrected.

In the light source device 11 in FIG. 4, the first position adjuster 80 and the second position adjuster 81 carry out position adjustment in the optical axial direction, and the third position adjuster 82 adjusts the position in the direction perpendicular to the optical axis, however, the adjustment directions for each adjusting part are not limited in the state in FIG. 4. For example, a measure may be provided in the first position adjuster 80 and the second position adjuster 81 for making positional adjustments of the condenser lens 30 and the projection lens 31 in the direction perpendicular to the optical axis. Alternatively, a measure may be provided in the third position adjuster 82 for making positional adjustments of the surface emitting laser 20 and the electronic circuit board 90 in the direction perpendicular to the optical axis. Also, rather than providing all of the first position adjuster 80, the second position adjuster 81, and the third position adjuster 82, just any one of the position adjusters may be selected and installed.

However, when the light from each of the surface emitting laser elements 21 of the surface emitting laser 20 widens by way of the projection optical system 15, the effect from distortion aberration may cause distortion in the image on the irradiated surface P2. In other words, image magnification will differ according to the irradiated region. Even in the above described case of projecting light on the fully irradiated region E3, illuminance irregularities (variations in illuminance due to the different region on the irradiated surface P2) caused by distortion on the image surface occur. These illumination irregularities are caused by aberrations in the projection optical system 15 that emits the widened light and might possibly occur in both the standard state in FIG. 2A and the irradiated region adjustment state in FIG. 3A.

Distortion aberration includes pincushion distortion that contracts the center of the image and stretches out the peripheral part, and barrel distortion that expands the center of the image and contracts the peripheral part. In pincushion distortion, the image on the irradiated surface P2 becomes greatly distorted (stretched out) the more the surface emitting laser elements 21 are mounted toward the peripheral part on the light emitting surface P1 of the surface emitting laser 20 and the illuminance per unit area (light amount) decreases. In barrel distortion, the image on the irradiated surface P2 becomes greatly distorted (stretched out) the more the surface emitting laser elements 21 are mounted toward the center on the light emitting surface P1 of the surface emitting laser 20 and the illuminance per unit area (light amount) decreases.

In the light source device 11 of the present embodiment, setting the surface emitting laser 20 prevents illuminance irregularities on the irradiated surface P2 caused by an aberration in the projection optical system 15. In other words, in the surface emitting laser 20, the light emission amount per unit area of the light emitting region corresponding to the irradiated region where the magnification by the projection optical system 15 is relatively large, is set larger than the light emission amount per unit area in the light emitting region corresponding to the irradiated region where the magnification by the projection optical system 15 relatively small. Measures to make this type of illuminance uniform are a first state that changes the spacing between the surface emitting laser elements 21, and a second state that makes different the light emission amounts of the surface emitting laser elements 21.

The first state illuminance uniformity that changes the spacing between the surface emitting laser elements 21 is described. This setting example deals with the case that light from the surface emitting laser 20 widens to a wide angle during projection by the projection optical system 15 and pincushion distortion consequently occurs in the image on the irradiated surface P2.

FIG. 6 illustrates the illumination distribution on the irradiated surface P2 when the neighboring surface emitting laser elements 21 of the surface emitting laser 20 are all placed equidistantly as the illumination distribution Tv1. The horizontal axis in FIG. 6 expresses the angle in the horizontal direction, and the vertical axis expresses the illumination ratio on the irradiated surface P2 (highest illuminance point is 100%).

The illuminance distribution Tv1 for equidistant placement of the surface emission laser elements 21 is a curve shape with the lighting range in the center as the strongest value and the intensity declining while proceeding to the peripheral area due to the effects of the distortion aberration from the projection optical system 15. In this illuminance distribution Tv1, the angle width in the horizontal direction equivalent to an illuminance of 80% of the peak value where illuminance is most intense, is 106 degrees.

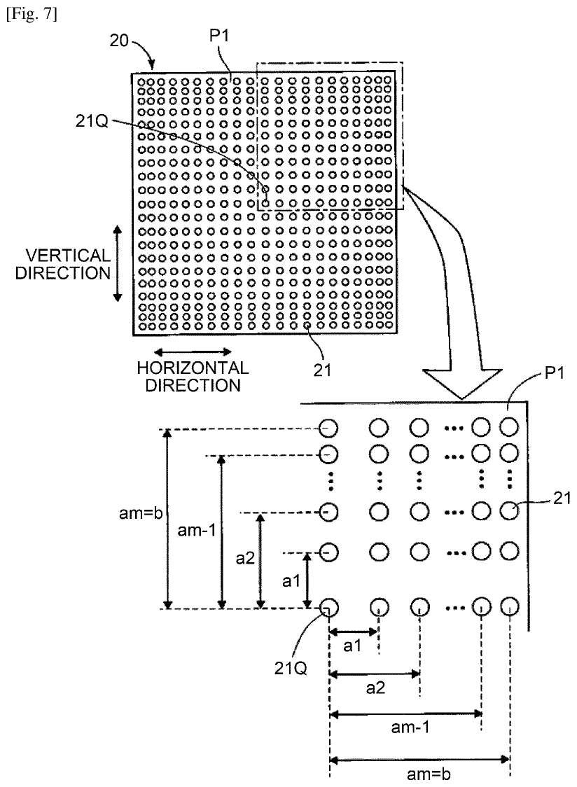

Here, as illustrated in FIG. 7, the density placement (set for non-uniform spacing) is set so that the spacing between neighboring surface emission laser elements 21 contracts or narrows from the center toward the periphery of the light emitting surface P1 for the surface emitting laser 20. In this way, the greater the extent (magnification) that the image on the irradiated surface P2 is stretched out towards the periphery, the larger the number of surface emitting laser elements 21 per unit area (density of placement is higher) on the corresponding light emitting surface P1 side, so that the illuminance uniformity on the irradiated surface P2 is improved compared to the case that the surface emitting laser elements 21 are placed equidistantly.

As one example of the present embodiment, the surface emitting laser elements 21 are placed as described below. The surface emitting laser 20 includes a total of 411 surface emitting laser elements 21 with 21 elements per each row/column in the vertical and horizontal directions within the light emitting surface P1 having a square shape with both of the dimensions in the vertical and horizontal directions are 1.44 mm. A surface emitting laser element 21Q (see FIG. 7) at the center in the center position in both the horizontal and vertical directions is enclosed by 10 surface laser emission laser elements 21 on each side in both the horizontal and vertical directions.

As seen from the surface emitting laser element 21Q in the center, the distance to one adjacently placed surface emitting laser element 21 is set as a1, the distance to the second placed surface emitting laser element 21 is set as a2, and the distance to the nth placed surface emitting laser element 21 is set as an (n=1, 2, . . . m). The maximum number of surface emitting laser elements 21 that can be placed in respective rows in the horizontal direction and columns in the vertical direction is set as N=2m+1(m≥1), the maximum distance that the surface emitting laser element 21 can be placed is set as b (am=b), the distance an satisfies the following relation.

an=b−α(N−1/2−n)^{β}

In the present embodiment, N=21, b=0.7 mm, and an=0.7 mm when N=10. Under these conditions, when finding the values for constants a, p at which the illuminance on the irradiated surface P2 becomes uniform, the values are α=0.05, β=1.15 regardless of the horizontal direction or the vertical direction. Then, the distance between the surface emitting laser element 21 at the farthest outer position and the surface emitting laser element 21 on that adjacent inner side on the light emitting surface P1 is a spacing with a minimum value of 49.6 μm regardless of the horizontal direction or the vertical direction. The spacing gradually increases between the adjacent surface emitting laser elements 21 towards the center, and the spacing (a1) between the surface emitting laser element 21Q in the center and the surface emitting laser element 21 on the next outer side is a maximum value of 80 μm.

The illuminance distribution on the irradiated surface P2 when the surface emitting laser elements 21 are placed at a density so as to satisfy the density for the above described condition is illustrated in FIG. 6 as the illuminance distribution Tw1. Upon comparing this illuminance distribution Tw1 with the illuminance distribution Tv1 for the case that the surface emitting laser elements 21 are placed equidistantly, the drop in intensity on the periphery is improved by using the illuminance distribution Tw1 and an overall uniform illuminance can also be obtained from the center to the periphery. For the illuminance distribution Tw when using this density distribution, the angle width in the horizontal direction equivalent to the illuminance of 80% of the peak value where the illuminance is most intense, is 143 degrees. The illuminance distribution Tw in the horizontal direction is illustrated in FIG. 6, however, in results from the density placement of the surface emitting laser elements 21 the drop in intensity on the periphery is improved in the vertical direction the same as in the horizontal direction. The conditions and numerical values for density placement of the surface emitting laser elements 21 as described above are one example of the present embodiment, and the conditions and numerical values for an appropriate density placement will vary according to the light source, the optical system structure or the state.

A suitable value for the density placement of the surface emitting laser elements 21 can be calculated and set at the design stage, according to the specifications such as for the projection optical system 15 and the surface emitting laser 20. In other words, the aberration in the projection optical system 15 is known at the design stage so illuminance irregularities in the irradiated region occurred from the effects by the aberration can also be calculated. Then, within the light emitting surface P1 of the surface emitting laser 20, by setting a higher placement density of the surface emitting laser elements 21 on the light emitting surface P1 side (by narrowing the spacing between the adjacent surface emitting laser elements 21), the light emission amount can be increased per unit area, and a uniform illuminance distribution can be obtained the closer to the region corresponding to the irradiated region where the projected image is relatively stretched out on the irradiated surface P2 (irradiated region with low illuminance per unit area). By carrying out a simulation on a computer for the design and calculating the density placement of the surface emitting laser elements 21 based on the optical design of the projection optical system 15, the surface emitting laser 20 optimized for the projection optical system 15 can be achieved without requiring the bother of performing measurement and adjustment tasks.

Illuminance uniformity can be achieved through density placement of the surface emitting laser elements 21 without having to change the light emission intensity of each of the surface emitting laser elements 21 so that there is no need to control the change in the amount of electrical current applied to each of the surface emitting laser elements 21. A compact light source drive circuit 16 capable of controlling the electrical current to the surface emitting laser 20 can therefore be achieved.

When the barrel distortion occurs in the image on the irradiated surface P2, unlike the example illustrated in FIG. 7 for a pincushion distortion, the surface emitting laser elements 21 can be set to a density placement having a narrow spacing with the adjacent surface emitting laser elements 21 that are more to the center rather than to the periphery of the light emitting surface P1 of the surface emitting laser 20.

In the present embodiment, the spacing of the adjacent surface emitting laser elements 21 are set to different hierarchical arrangements in the respective horizontal direction and the vertical direction, however, a structure may be employed that includes an area of uniform spacing between the adjacent surface emitting laser elements 21, and an area of different spacing between the adjacent surface emitting laser elements 21. For example, a structure that sets uniform spacing for the adjacent surface emitting laser elements 21 from the center of the light emitting surface P1 to a predetermined range, and that sets different spacing for the adjacent surface emitting laser elements 21 only on the periphery of the light emitting surface P1 may be employed. Alternatively, a structure that sets uniform spacing for the adjacent surface emitting laser elements 21 from the periphery of the light emitting surface P1 to a predetermined range, and sets different spacing for the adjacent surface emitting laser elements 21 just in the center of the light emitting surface P1 may be employed. To what extent and in which area to set the spacing of the light emitting surface P1 may be selected as needed according to the effect from the distortion aberration of the projection optical system 15.

Next, the second state illuminance uniformity carried out by varying the light emission amounts of the surface emitting laser elements 21 of the surface emitting laser 20 is described. This setting example deals with the case that light from the surface emitting laser 20 widens to a wide angle during projection by the projection optical system 15, and consequently pincushion distortion occurs in the image on the irradiated surface P2. The spacing between the adjacent surface emitting laser elements 21 is set to a fixed spacing.

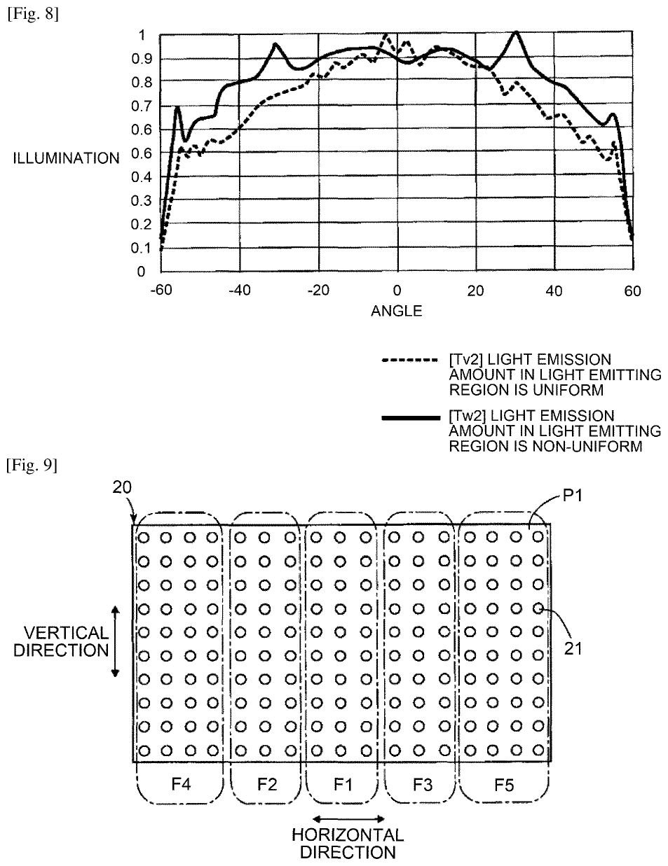

The illuminance distribution on the irradiated surface P2 when the light emission amount for each of the surface emitting laser elements 21 of the surface emitting laser 20 is set the same is illustrated in FIG. 8 as the illuminance distribution Tv2. The horizontal axis in the graph in FIG. 8 expresses the angle in the horizontal direction and the vertical axis expresses the illumination ratio on the irradiated surface P2 (the ratio of the location with the highest illuminance is 100%). By setting a common size for the applied current flow amount for each surface emitting laser element 21 and the amount for the current pass-through region 27a of the current constriction layer 27, each of the surface emission laser elements 21 will have the same light emission amount.

When the same light emission is set for each surface emitting laser element 21, the illuminance distribution Tv2 is a bell-shaped curve that has the peak in intensity at the center of the lighting range and progressively weakens towards the periphery due to the effect from the distortion aberration in the projection optical system 15. In this illuminance distribution Tv2, the angle width in the horizontal direction equivalent to the illuminance of 80% of the peak value where the illuminance is most intense, is 57 degrees.

In this embodiment, as illustrated in FIG. 9, the light emitting surface P1 is divided into five regions F1 to F5 in the horizontal direction and controlled to provide a different applied current amount for the surface emitting laser elements 21 in each region. More specifically, by increasing the amount of the applied current in steps while proceeding from F1 at the center of light emitting surface P1 towards the regions F4, F5 at positions on the periphery, the average output of the light emitted from each of the surface emitting laser elements 21 becomes higher the closer to the periphery of the light emitting surface P1. In this way, the greater the extent that the image is stretched out towards the periphery on the irradiated surface P2, the larger the light emission amount per unit area in the corresponding light emitting region of the surface emitting laser 20, so that the illuminance uniformity on the irradiated surface P2 is improved compared to when the current amount applied to each surface emitting laser element 21 is a fixed amount.

As one example, the applied current amount for each surface emitting laser element 21 is set so that light is emitted with average outputs of 1 W in region F1 at the center, 1.06 W in region F2 and region F3 on one outer side of region F1, and 1.29 W in region F4 and region F5 on the outermost periphery. The sizes of the current pass-through region 27a of the current constriction layer 27 are set to 9 μm in region F1, 9.2 μm in region F2 and region F3, and 10 μm in region F4 and region F5 that correspond to the differences in the applied current amount.

The illuminance distribution on the irradiated surface P2 when the applied current amount for each of the regions F1 to F5 is set as described above is illustrated as an illuminance distribution Tw2 in FIG. 8. In the illuminance distribution Tw2, the drop in intensity on the periphery in the illuminance distribution Tv2 in the case of the fixed applied current amount is improved, and the angle width in the horizontal direction equivalent to the illuminance of 80% of a peak value where the illuminance is most intense, is 85 degrees.

When the barrel distortion occurs on the irradiated surface P2, unlike the above example describing dealing with the pincushion distortion, the amount of current that is applied to the surface emitting laser elements 21 is increased proceeding from region F4 and region F5 on the peripheral side towards the region F1 at the center side in the surface emitting laser 20. In other words, the light emission amount per unit area is set to become large at region F1 at the center side, and the light emission amount per unit area is set to become small at region F4 and region F5 on the periphery side.

The applied current amount for each surface emitting laser element 21 can be changed by control from the light source drive circuit 16 so dynamic adjustment of the illuminance distribution can be performed after completion of the light source device 11.

The above method is the method that changes the amount of current applied to the each surface emitting laser element 21, however, even by just changing the size of the current pass-through region 27a of current constriction layer 27 after setting the amount of current applied to each surface emitting laser element 21 to a fixed value, the light emission amount of the each surface emitting laser element 21 can be changed and an effect of uniform illuminance on the irradiated surface P2 is obtained. By reducing the size of the current pass-through region 27a, the oscillation threshold of the surface emitting laser element 21 becomes low so that compared to the surface emitting laser element 21 with relatively large size of the current pass-through region 27a, the average output of light that is emitted when a fixed amount of current is applied becomes large. Therefore, within the light emitting surface P1, the more the surface emitting laser element 21 is at a position requiring the increase of the light intensity, the smaller the size of the current pass-through region 27a becomes. However, the size of the current pass-through region 27a is determined by the selectable range according to the electrode structure of each surface emitting laser element 21 so that the settings must be made within the applicable range.

In the present embodiment, the light emitting surface P1 is divided into five regions F1 to F5 in the horizontal direction and controlled to provide different light emission amounts for the surface emitting laser elements 21 in each region. Unlike the present embodiment, the light emission amount of the surface emitting laser elements 21 grouped into a plurality of regions in the vertical direction can be controlled, or the light emission amount of the surface emitting laser elements 21 in each region separated into tile types in both the horizontal direction and the vertical direction can be controlled. Moreover, a shape other than a tile (box) shape may be set in different ranges for the surface emitting laser elements 21. Also, even in cases where there are a small number of the surface emitting laser elements 21, all of the surface emitting laser elements 21 can be controlled at different light emission amounts.

As described above, the illumination uniformity can be performed in the irradiated region by joint use of the first method (FIG. 6, FIG. 7) that changes the spacing (setting the coarse and dense placement) of the surface emitting laser elements 21, and the second method (FIG. 8, FIG. 9) that changes the light emission intensities of the surface emitting laser elements 21.

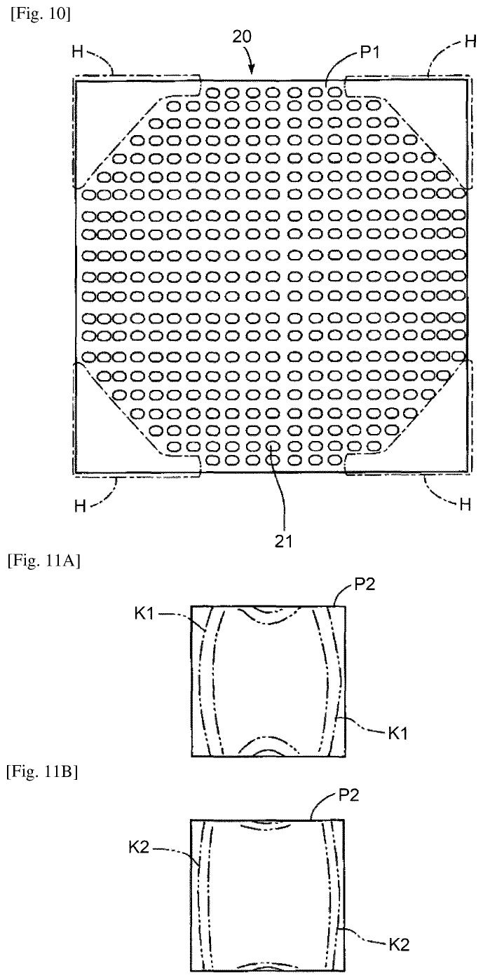

FIG. 10 and FIG. 11 illustrate examples of changing the shape of the irradiated region on the irradiated surface P2 by setting the setting range of the surface emitting laser element 21 on the light emitting surface P1. These setting examples, deal with the occurrence of pincushion distortion in the image on the irradiated surface P2 that causes the projection optical system 15 to widen the angle of the light and project if from the surface emitting laser 20 in a wide angle.

FIG. 11A illustrates the lighting region on the irradiated surface P2 in the case when the surface emitting laser elements 21 are placed over the entire rectangular light emitting surface P1. The structure on the light emitting surface P1 side corresponding to FIG. 11A is omitted from the drawing, however, the same as the structure illustrated in FIG. 7, the spacing for each of the surface emitting laser elements 21 is formed in a density placement that widens at the center of the light emitting surface P1 and contracts at the periphery.

A concept view of the boundary where a large difference in illumination occurs is illustrated in FIG. 11A with a two-dot chain line and the contour line K1 as the approximate outer contour of the lighting region. As can be seen from this drawing, the distortion is becoming large in the irradiated region in the peripheral areas of the irradiated surface P2 and particularly in the vicinity of the four corners due to the effect of the distortion aberration from the projection optical system 15.

In FIG. 10, on the rectangular light emitting surface P1 of the surface emitting laser 20, the areas at the four corners are non-light emission areas H where no surface emitting laser elements 21 are installed, and the light-emission area formed by the surface emitting laser elements 21 are all set as oval shapes. In the light emission areas (area that the surface emitting laser elements 21 are placed) set as oval shapes, the density placement is arranged so that the spacing between the surface emitting laser elements 21 is wider in the center of the light emitting surface P1, and narrow toward the periphery. The non-light emission areas H may employ a structure that has no physical structure for the surface emitting laser elements 21 such as illustrated in FIG. 5, or may include the surface emitting laser elements 21 as structures but need not control them as elements to emit light.

FIG. 11B illustrates the illumination on the irradiated surface P2 when the installation range for the surface emitting laser element 21 is set in an oval shape (FIG. 10). The boundary at which a large difference occurs is illustrated as a concept view using a two-dot chain line the same as in FIG. 11A, and the contour line K2 is the approximate outer contour of the lighting region. By setting the four corners of the light emitting surface P1 as the non-light emission areas H, an irradiation area in a nearly rectangular shape (contour line K2) is formed having no large distortion in the irradiation in the four corner areas of the irradiated surface P2 such as in FIG. 11A. The regions corresponding to the periphery that the image is stretched out in large due to distortion aberration are set as the non-light emission areas H in the light emitting surface P1 so that variations in the illumination on the periphery of the irradiated region are suppressed.

The light emitting surface P1 and the irradiated surface P2 in this way have a corresponding relationship so that by changing the range of the setting for placing the surface emitting laser elements 21 on the light emitting surface P1 side, the shape of the irradiated region on the irradiated surface P2 can be changed. Therefore, in the distance measurement device 10 (FIG. 1), by emitting the light from the light source device 11 so as to form an irradiated region corresponding to the shape of the photodetector 13, irradiation onto an unnecessary region can be avoided and the utilization efficiency of the light can be improved.

As described above, in the light source device 11 to which the present invention is applied, the light emission amount per unit area in the light emitting region of the surface emitting laser 20 is changed according to the irradiated region so as to reduce irregularities in the illumination caused by effects from aberrations in the projection optical system 15. In this way, a high quality light source device 11 that is satisfactory for both projecting wide angle light onto the object for irradiating and illuminance uniformity can be obtained. By projecting light with superior illuminance uniformity from the light source device 11, the detection accuracy in the distance measurement device 10 (or a general-purpose device including applications other than distance measurement) utilizing the light source device 11 can be improved.

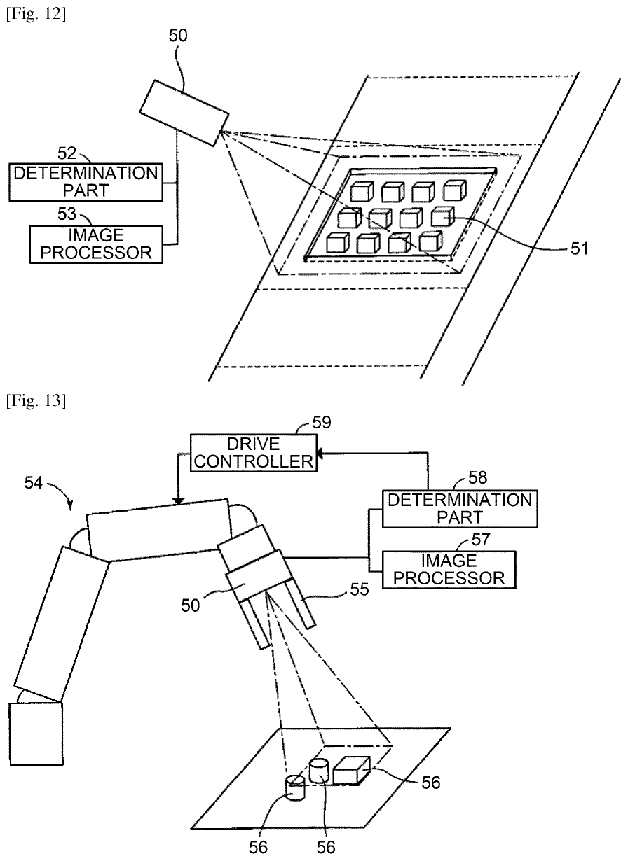

Examples applying the light source device 11 described above in various types of electronic apparatuses are described while referring to FIG. 12 to FIG. 16. A detection device 50 for these application examples is a detection device that a portion of the signal control circuit 17 of the distance measurement device 10 illustrated in FIG. 1 is substituted into the respective latter described function blocks, and other portions of the basic structure are in common with the distance measurement device 10. In the detection device 50, the photodetector 13 illustrated in FIG. 1 is a determination part that detects light emitted from the light source device 11 and reflected on the detection target object 12. In FIG. 12 to FIG. 16, the function blocks including a determination part and the like of the detection device 50 are illustrated on the outer side of the detection device 50 for purposes of convenience in making the drawings.

FIG. 12 illustrates an example of applying the detection device 50 to inspection of articles at a factory, etc. The light emitted from the light source device 11 of the detection device 50 projects upon an irradiated region covering a plurality of articles 51 and the reflected light is received by the detector part (photodetector 13). A determination part 52 determines the state of each article 51 based on information detected by the detector part. Specifically, an image processor 53 generates image data (image information of the irradiated region by the light from the light source device 11) based on the electrical signals that are optically-electrically converted by the photodetector 13, and the determination part 52 determines the state of each article 51 based on the obtained image information. In other words, the light-receiving optical system 18 and the photodetector 13 of the detection device 50 function as an imaging measure that captures the projected region by the light from the light source device 11. Known image analysis techniques such as pattern matching can be utilized by the determination part 52 to determine the state of the article 51 based on the captured image information.

In the application example in FIG. 12, utilizing the detection device 50 (light source device 11) capable of projecting light with uniform illuminance onto the irradiated region can suppress irregularities in the illuminance even when emitting light at a wide angle. As a result, numerous articles 51 can be simultaneously inspected with good accuracy and the work efficiency of the inspection can be improved. Utilizing the detection device 50 that performs detection by the TOF (time-of-flight) method allows obtaining information in the depth direction of each article 51 and not just the forward side (side facing the detection device 50) of each article 51. Therefore, compared to a visual inspection by the existing image capturing device, tiny scratches and faults on each of the article 51, and the three-dimensional shape and so on can be easily identified and the inspection accuracy improved. The light from the light source device 11 of the detection device 50 can illuminate the irradiated region including the article 51 that is a target for inspection and so can be used even in dark environments.

FIG. 13 illustrates an example applying the detection device 50 to controlling the operation of a movable device. An articulate arm 54 serving as the movable device includes a plurality of arms connected by bendable joints and includes a hand part 55 at the tip of the arm. The articulated arm 54 is utilized for example on assembly lines in factories, and the hand part 55 grasps a target article 56 during inspections, conveying, or assembly of the target article 56.

The detection device 50 is mounted directly near the hand part 55 on the articulated arm 54. The detection device 50 is installed so that the light projection direction matches the direction the hand part 55 faces, and the target article 56 and the peripheral region are set as the detection target. The detection device 50 receives the reflected light from the irradiated region including the target article 56 at the photodetector 13, generates image data in an image processor 57 (performs image capture), and determines the various types of information relating to the target article 56 in a determination part 58. Specifically, the information detected by utilizing the detection device 50 is a distance to the target article 56, a shape for a target article 56, a position for a target article 56, and mutual position relation when there is a plurality of target articles 56 present, etc. A drive controller 59 then controls the operation of the articulated arm 54 and the hand part 55 based on determination results in the determination part 58 to grasp the target article 56 and move, etc.

The application example in FIG. 13 is capable of rendering the same effects as the detection device 50 in FIG. 12 described above (improved detection accuracy) regarding detecting the target article 56 by way of the detection device 50. In addition, by mounting the detection device 50 on the articulated arm 54 (especially, directly near the hand part 55), the target article 56 for the grasp can be detected from a short distance away, and the detection accuracy and the recognition accuracy can be improved compared to the detection performed remotely by the image capturing device from a position away from the articulated arm 54.

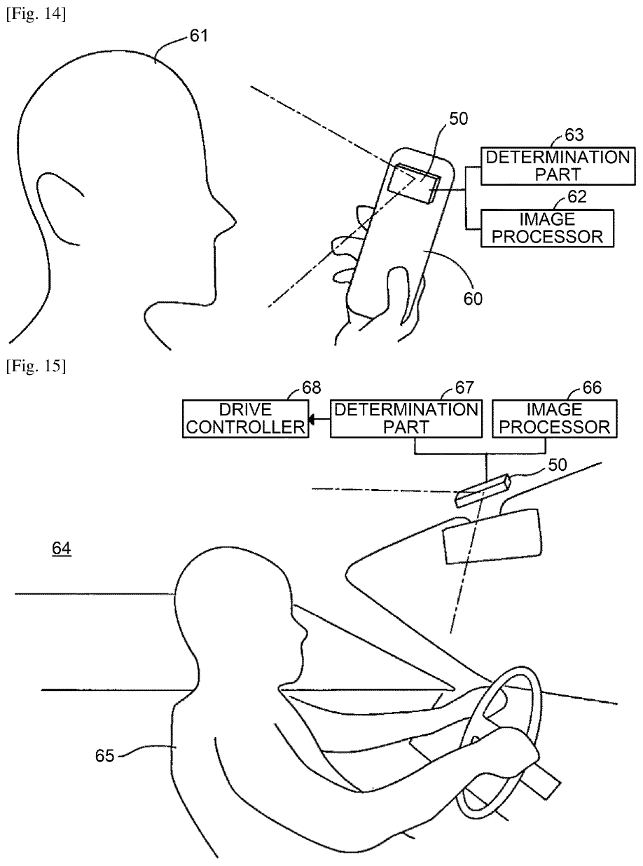

FIG. 14 illustrates an application example utilizing the detection device 50 for authenticating the user of electronic apparatus. A portable information terminal 60 serving as the electronic apparatus includes an authentication function for the user. The authentication function may be achieved by dedicated hardware or may be achieved with the central processing unit (CPU) that controls the portable information terminal 60 executing a program such as in a read only memory (ROM).

During authentication of the user, light from the light source device 11 of the detection device 50 installed in the portable information terminal 60 is projected towards a user 61 using the portable information terminal 60. The photodetector 13 of the detection device 50 receives the light reflected from the user 61 and the periphery, and the image processor 62 generates image data (performs image capture). A determination part 63 determines the coincidence that the image information from capturing an image of the user 61 by way of the detection device 50 matches the preregistered user information and decides whether the user 61 is the registered user or not. Specifically, the contours (profile and irregularities) of the face, the ears, and the head of the user 61 are measured and can be utilized as user information.

The application example in FIG. 14 can achieve the same effect (improve the detection accuracy) as the detection device 50 in the above described FIG. 12 in regards to detecting the user 61 by way of the detection device 50. In particular, information on the user 61 can be detected by projecting light from the light source device 11 at uniform illumination and a wide angle over a wide range so that a large volume of information on the user can be obtained and the authentication accuracy can be improved compared to when the detection range is narrow.

In the example in FIG. 14, the detection device 50 is installed in the portable information terminal 60, however, authentication of the user can also be achieved by installing and utilizing the detection device 50 installed in an office automation apparatus such as desktop personal computers and printers, and security systems for buildings, etc. The function aspect is not limited to authenticating individuals and may be utilized for scanning three-dimensional shapes such as faces. In that case, installing the detection device 50 (light source device 11) capable of emitting light at uniform illuminance over a wide angle can achieve high accuracy scanning.

FIG. 15 illustrates an application example utilizing the detection device 50 in a drive support system in moving units such as vehicles. A vehicle 64 includes a drive support function capable of automatically performing a portion of driving operations such as deceleration and steerage. The drive support function may be implemented by dedicate hardware or may be implemented by an electronic control unit (ECU) for controlling the electrical system of the vehicle 64 executing a program such as on the ROM.

The light source device 11 for the detection device 50 installed onboard the vehicle 64 emits light toward a driver 65 operating the vehicle 64. The photodetector 13 of the detection device 50 receives the light reflecting from the user 65 and the periphery, and an image processor 66 generates image data (performs image capture). A determination part 67 determines information such as the face (expression) or stance of the user 65 based on image information obtained by capturing the driver 65. A drive controller 68 then controls the braking and steering based on determination results from the determination part 67 and performs appropriate drive support according to the state of the driver 65. For example, when the driver taking his eyes off the road is detected or dozing while driving is detected, the drive controller 68 can automatically reduce the vehicle speed or automatically stop the vehicle.

The application example in FIG. 15 can achieve the same effect (improving detection accuracy) as the detection device 50 in the above described FIG. 12 in regards to detecting the state of the driver 65 by way of the detection device 50. In particular, information on the driver 65 can be detected by projecting light from the light source device 11 at a uniform illuminance and a wide angle over a wide range so that a large volume of information can be obtained compared to when the detection range is narrow, and the accuracy of the drive support is improved.

FIG. 15 is an example illustrating the detection device 50 mounted in the vehicle 64, however, the detection device 50 is also applicable to moving units other than vehicles such as trains and airplanes. Besides detecting the faces and stances of drivers and operators, targets for detection may also include the state of the passengers in each seat or also the state within the vehicle other than the passenger seats. The function aspect is also capable of utilizing individual authentication of the driver the same as in the application example of FIG. 14. For example, control to allow starting the engine, locking the door locks or unlocking the door locks can be implemented just by detecting the driver 65 by utilizing the detection device 50 and determining a match with the preregistered driver information.

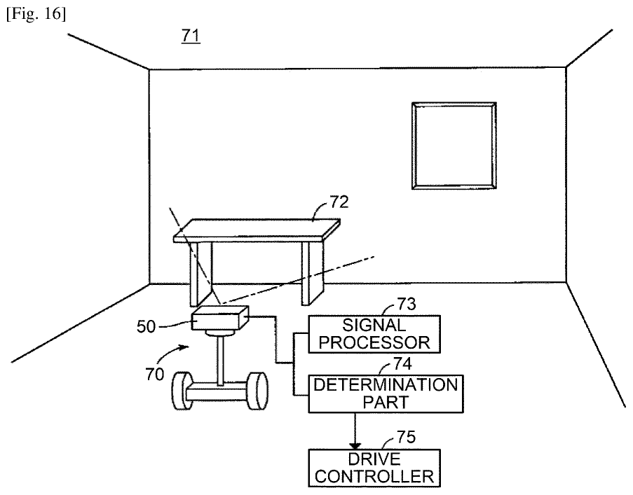

FIG. 16 is an application example illustrating the usage of the detection device 50 in an autonomous driving system in a moving unit. Unlike the application example in FIG. 15, the application example given in FIG. 16 utilizes the detection device 50 in sensing of target objects outside a moving unit 70. The moving unit 70 is an autonomous driving type moving unit capable of recognizing outside situations while during automatic driving.

The detection device 50 is installed in the moving unit 70. The detection device 50 emits light in the forward movement direction and the peripheral region of the moving unit 70. In a room interior 71 serving as the movement area of the moving unit 70, a desk 72 is placed in the forward movement direction of the moving unit 70. Among the light projected from the light source device 11 of the detection device 50 installed in the moving unit 70, the light reflected from the desk 72 and its periphery is received at the photodetector 13 of the detection device 50, and the optically-electrically converted electrical signal is sent to a signal processor 73. The signal processor 73 internally calculates information relating to the room interior 71 layout such as the distance to the desk 72, the position of the desk 72, and the peripheral state of other than the desk 72 based on the electrical signals sent from the photodetector 13. A determination part 74 determines the movement path and movement speed of the moving unit 70 based on this calculated information and a drive controller 75 controls the driving of the moving unit 70 (operation of the motor serving as the drive force) based on determination results from the determination part 74.

In the application example in FIG. 16, the detection device 50 can achieve the same effect (improved detection accuracy) as the detection device 50 in the above described FIG. 12 in regards to layout detection in the room interior 71 by the detection device 50. In particular, information on the room interior 71 can be detected by projecting light from the light source device 11 at uniform illuminance and the wide angle over the wide range so that a large volume of information compared to when the detection range is narrow can be obtained, and the accuracy of the autonomous driving of the moving unit 70 can be improved.

FIG. 16 is an example of installing the detection device 50 in autonomous driving type moving unit 70 driving in the room interior 71, however, the detection device 50 can also be applied to outdoor autonomous driving type vehicles (so-called automatic drive vehicles). The detection device 50 can also be applied not only to autonomous driving type but to drive support system in moving units such as vehicles driven by a driver. In this case, utilizing this detection device 50 allows detecting the peripheral state of the moving unit, and allows support for driving by the driver according to the detected peripheral state.

The present invention is described above based on the represented embodiment, however, the present invention is not limited by the above described embodiments and may include all manner of modifications and improvements within the spirit and scope of the present invention.

In the above described embodiment, the surface emitting laser 20 is utilized for overall surface light emission by arraying the surface emitting laser elements 21 in the horizontal direction and in the vertical direction as the light source, however, a line type light source having a light emitting region only in a specified direction such as a horizontal direction or a vertical direction may also be utilized.

Besides the VCSEL of the above described embodiment, edge emitting lasers and light emitting diodes (LED) may be utilized as the light source. As described above, the VCSEL has advantages in the points of forming a two-dimensional light emitting region and allowing a high degree of freedom in placement of the light emitting regions, however, even if light sources other than VCSEL are utilized, the same effect as in the above described embodiment can be obtained by appropriately setting the light emission intensity and the placement of each light emission element.

### REFERENCE SIGNS LIST

10 Distance measurement device

11 Light source device

13 Photodetector (detector part)

14 Light source

15 Projection optical system

16 Light source drive circuit

17 Signal control circuit (calculation part)

18 Light-receiving optical system

20 Surface emitting laser (light source)

21 Surface emission laser element (light emitter)

27 Current constriction layer

30 Condenser lens (light condensing optical element)

31 Projection lens (magnifying optical element

50 Detection device

54 Articulate arm (electronic apparatus)

60 Portable information terminal (electronic apparatus)

64 Vehicle (electronic apparatus)

70 Moving unit (electronic apparatus)

80 First position adjuster

81 Second position adjuster

82 Third position adjuster

E1 Irradiated region

E2 Non-irradiated region

E3 Fully irradiated region

H Non-light emission area

P1 Light emitting surface

P2 Irradiated surface

1. A light source device comprising:
a light source including a plurality of light emitters; and
a projection optical system configured to emit light emitted from the light source, wherein
a light emission amount per unit area in a light emission region of the light source corresponding to an irradiated region where a magnification of the projection optical system is relatively large, is larger than a light emission amount per unit area in a light emission region corresponding to an irradiated region where a magnification of the projection optical system is relatively small.

2. The light source device according to claim 1, wherein a spacing between adjacent light emitters of the plurality of light emitters is different in at least a portion of the light source.

3. The light source device according to claim 1, wherein a light emission amount of a light emitter is different in at least a portion of the light source.

4. The light source device according to claim 1, wherein current amounts applied to the plurality of light emitters are the same.

5. The light source device according to claim 1, wherein
a magnification of the projection optical system in a periphery of the irradiated region is larger than a magnification in a center, and
a light emission amount per unit area in a light emission region corresponding to the periphery of the irradiated region is larger than a light emission amount per unit area in a light emission region corresponding to the center of the irradiated region.

6. The light source device according to claim 1, wherein
the projection optical system comprising:
a light condensing optical element configured to suppress a divergence angle of light emitted from the light source; and
a magnifying optical element configured to magnify a light emission angle of light transmitted through the light condensing optical element, and emit the light.

7. The light source device according to claim 6, further comprising a first position adjuster configured to move the light condensing optical element relative to the light source or to the magnifying optical element.

8. The light source device according to claim 7, wherein the first position adjuster is able to adjust a position of the light condensing optical element at least in an optical axial direction.

9. The light source device according to claim 6, further comprising a second position adjuster configured to move the magnifying optical element relative to the light source or to the light condensing optical element.

10. The light source device according to claim 9, wherein the second position adjuster is able to adjust a position of the magnifying optical element at least in an optical axial direction.

11. The light source device according to claim 6, further comprising a third position adjuster configured to move the light source relative to the projection optical system.

12. The light source device according to claim 11, wherein the third position adjuster is able to adjust a position of the light source at least in a direction perpendicular to the optical axis.

13. The light source device according to claim 1, wherein the light source is any of a vertical resonator surface emission laser, an edge-emitting laser, or a light emitting diode.

14. A detection device comprising:
a light source device according to claim 1; and
a detection part configured to detect light emitted from the light source device and reflected at a target object.

15. The detection device according to claim 14, comprising a calculator configured to obtain information relating to a distance to the target object based on a signal from the detection part.

16. An electronic apparatus configured to receive information from the detection device according to claim 14, the electronic apparatus comprising a controller configured to control the electronic apparatus based on information from the detection device.
